(19) United States
(12) Patent Application Publication
(10) Pub. No.: US 2005/0126483 A1
(43) Pub. Date: Jun. 16, 2005

(54) Arrangement for depositing atomic layers on substrates

(76) Inventor: Marcel Tognetti, Kea'au, HI (US)

Correspondence Address: SLATER & MATSIL LLP, 17950 PRESTON ROAD, SUITE 1000, DALLAS, TX, 75252, US

(21) Appl. No.: 10/954,006

(22) Filed: Sep. 29, 2004

(30) Foreign Application Priority Data
Sep. 30, 2003 (DE) 103 45 824.7

(51) Int. Cl. C23C 16/00

(52) U.S. Cl. 118/715

(57) ABSTRACT

An arrangement for depositing atomic layers on substrates produces very thin films in an evacuable reaction chamber. Substrates or wafers are arranged on a wafer chuck and the reaction chamber is connected via valves to a source for TMA, water and a cleaning gas. The invention is intended to significantly improve the coating process. This is achieved by virtue of the fact that the source for TMA and the source for water are connected to the reaction chamber via devices for directly or indirectly injecting the TMA and the water into the reaction chamber. It is preferable for the devices for injection to comprise valves, which are designed as injection valves.

This application claims priority to German Patent Application 103 45 824.7, which was filed Sep. 30, 2003, and is incorporated herein by reference.

### TECHNICAL FIELD

The invention relates to an arrangement for depositing atomic layers on substrates to produce very thin films in an evacuable reaction chamber, the substrates or wafers being arranged on a wafer chuck and the reaction chamber being connected via valves to a source for TMA, water and a cleaning gas.

### BACKGROUND

The deposition of atomic layers, i.e., atomic layer deposition (ALD), has recently also been used in the commercial production of semiconductors. However, the devices that are currently available for this process are insufficiently stable, and consequently are not optimized for mass production.

The process known as ALD involves the deposition of monolayers in a self-limiting environment. In this process, two process gases or vapors are alternately introduced in short cycles into the ALD reactor using a purge gas, with monolayers being deposited in the form of a film on the semiconductor wafer. Process instabilities have been observed in particular during the deposition of liners, preventing uniform deposition both on the wafer and from wafer to wafer. By way of example, aluminum oxide can be deposited on the wafer using this process.

FIG. 1 (prior art) shows the functional principle of an ALD wafer reaction chamber. A wafer chuck 2, on which a wafer 3 is heated to the required process temperature, is situated in the reaction chamber 1. The aluminum source used is trimethylaluminium vapor (TMA), the oxygen source used is water vapor, or in some cases ozone, and the purge gas used is an inert gas.

After the wafer has been arranged in the reactor 1, the valve Vp1 is opened, so that the vapor can flow out of a TMA bubbler 4 into the reactor 1. The TMA vapor is generated by a carrier gas, which is controlled by a flow controller 5, being passed through the TMA bubbler 4, entraining TMA and passing it through a constriction 6 into the reactor 1. At the moment at which the valve Vp1 is closed, the valve Vp1 is switched over to admit the purge gas. After the reactor 1 has been sufficiently purged, water vapor is passed out of a water vapor bubbler 7 via a constriction 10 into the reactor 1 using the same basic principle, for which purpose valve Vp2 is opened.

Then, purge gas is once again passed into the reactor. This cycle (TMA, purge, water vapor, purge) is repeated until a sufficiently thick film has been deposited on the wafer 3. During this process, the pressure in the reactor is controlled by a pressure regulator PID. The pressure is measured with the aid of a pressure-measuring device 8 and controlled with the aid of a throttle valve.

The valves Vp1 and Vp2 are fast-switching valves which allow a flow to take place within very short cycle times. By way of example, in the case of the liner process, the cycle times, i.e., the TMA and water vapor pulse times, are in the range of a few tens of milliseconds and the purge times are in the range of seconds.

The process described is extremely dynamic on account of the short valve cycle times. Since standard PID pressure regulators are used, none of these regulators reaches a desired valve within the predetermined time. A similar statement also applies to the carrier gas controller.

The flow of a carrier gas through a bubbler requires a constant flow for a stable discharge. Only limited quantities of vapor are entrained by a pulsating flow. The quantity of vapor entrained is directly dependent on the temperature of the liquid. Slight temperature changes may significantly alter the quantity of vapor entrained. Since the pulse times are so short, only a few bubbles if any are passed through the liquid, resulting in an extremely unstable flow of vapor with respect to the carrier gas flow.

Furthermore, a constriction (a passage or a needle valve used as a passage) downstream of the bubbler 4, 7 generates a gas buffer, possibly as a function of the size of the passage, when the corresponding valve Vp1, Vp2 is closed. The pressure is stabilized and becomes equal on both sides of the passage. If Vp1/Vp2 is then opened, the mixture of carrier gas and vapor downstream of the passage 6 expands into the reactor 1 (pressure drop). Therefore, it takes a certain time for the flow into the reactor to be stabilized again. During this time, valve Vp1/Vp2 has already closed again and the volume between the passage and the valve is refilled.

This may at the current time be an acceptable and reproducible way of passing small quantities of gas into the reactor. However, the reproducibility is dependent on the pressure and gas temperature and on the reproducibility of the concentration.

It is customary to use pneumatically actuated standard valves. Valves of this type are not designed for high-speed switching operations and, therefore, have an insufficient service life. Since faults cannot be detected in good time, valves of this type lead to an unstable process. Also, the reaction time of the pneumatically actuated valves is too long, with the result that it is possible that the valves will not open completely. How far the valves open depends on various factors, such as the pressure of the control air or alternatively also the friction in the valve drive. The quantity of gas passed through the valve changes rapidly over the course of time and as a function of the temperature.

The valves which are currently used are three-way valves which are installed in such a way that purge gas flows when no vapor is flowing. Most three-way valves have a very short time in which both ports are open to the outlet, so that purge gas can flow into the vapor section or via versa.

On account of the pulsed process, it is difficult to set a stable process pressure by means of the pressure regulator.

One possible way of improving the process flow is to use TMA and water evaporators instead of the bubblers and to introduce them into the reactor without carrier gas via valves and constrictions.

One problem in this context is that it is not a mixture of carrier gas and TMA or water vapor that is introduced. The quantity of the TMA is controlled by a supercritical opening, which is associated with aluminum “bleeding” during the “off time.” To stabilize the process in this case, the pure TMA or the water vapor and the purge gas can be passed jointly into the reactor. In this way, it is possible for the concentration of TMA and water vapor in the purge gas flow to be controlled with sufficient reproducibility.

The particular drawback of this variant is that although it can be realized without major alterations to the device, it would significantly alter the process previously employed.

### SUMMARY OF THE INVENTION

In one aspect, the invention provides an arrangement for the deposition of atomic layers, which significantly improve the coating process.

In one embodiment, the source for TMA and the source for water are connected to the reaction chamber via devices for directly or indirectly injecting the TMA and the water into the reaction chamber.

The particular advantage of the invention is that extremely small quantities of liquid can be injected, and such quantities have no effect on the internal pressure in the reaction chamber, and consequently stable operation is possible.

It is advantageous if the devices for injection comprise valves which are designed as injection valves, in which case motor vehicle injection valves or modifications thereof may be particularly suitable.

In a variant of the invention, the devices for injecting the TMA liquid and the water into the reaction chamber are connected to the reaction chamber via a mixing chamber, in which case the mixing chamber is connected to a purge gas source. This makes it possible to achieve a uniform distribution of the TMA liquid or the water in the reaction chamber.

Finally, a TMA tank is provided as the source for TMA, and an H₂O bubbler is provided as the source for water.

The particular feature in this context is that the TMA tank and the H₂O tank are each connected to a propellant gas source in such a manner that an internal pressure is in each case built up, propelling the TMA out of the TMA tank or the water out of the H₂O tank.

### BRIEF DESCRIPTION OF THE DRAWINGS

The invention is to be explained in more detail below on the basis of an exemplary embodiment. In the associated drawings:

FIG. 1 diagrammatically depicts an ALD reactor with associated feeds for carrier and purge gas TMA and water vapor (prior art); and

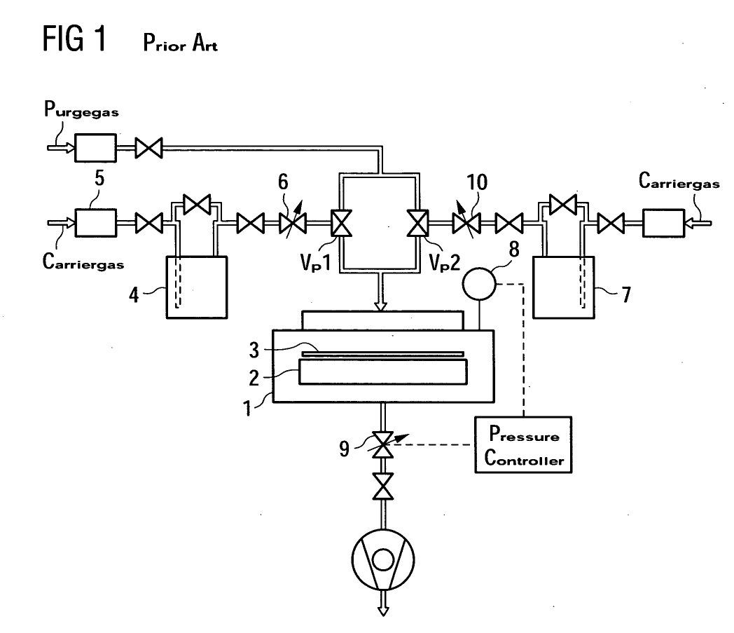

FIG. 2 diagrammatically depicts an ALD reactor equipped with injection valves.

The Following list of reference numerals can be used in conjunction with the figures:
1 reaction chamber
2 wafer chuck
3 wafer
4 TMA bubbler
5 flow controller
6 passage
7 H₂O bubbler
8 pressure-measuring device
9 throttling valve
10 passage
11 pressure regulator
12 TMA tank
13 propellant gas source
14 vacuum pump
15 pressure-regulating device
16 mixing chamber
17 valve
18 mass flow controller
19 purge gas source
20 H₂O tank
21 pressure regulator
22 propellent gas source
Vp1 valve
Vp2 valve
PID pressure regulator

### DETAILED DESCRIPTION OF ILLUSTRATIVE EMBODIMENTS

One idea of the invention consists in using injection valves as used in the automotive industry to control the combustion process in spark-ignition engines, either directly or in modified form, to control the flow of gas. These injection valves make it possible to realize intervals of 50 ms without any problems. Therefore, injection valves of this type can quite easily replace the valves, which have hitherto been used, since the quantity of the liquid injected can be accurately controlled.

If an evaporation system that switches between vapor and purge gas is used, it is possible to achieve further stabilization by cooling the throttling valve used to control the reactor pressure. On the other hand, the stability of the pressure in the reaction chamber is no problem in the case of direct injection.

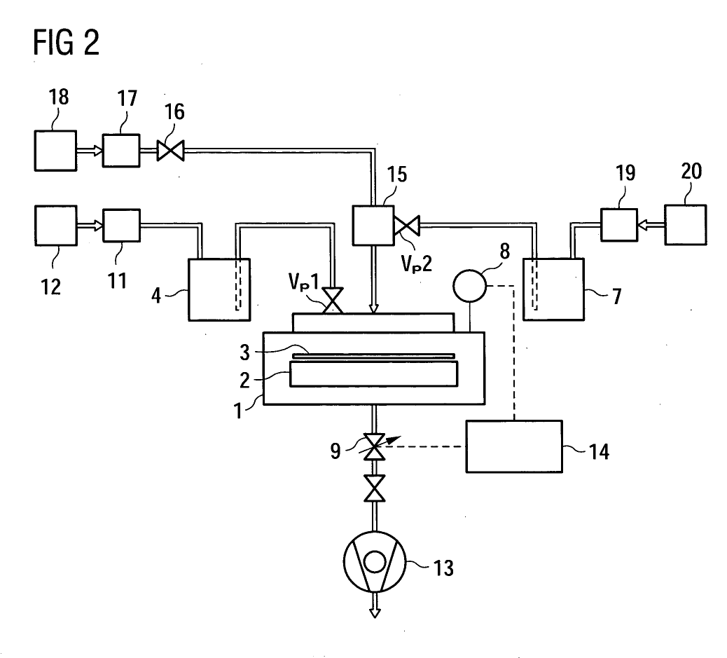

FIG. 2 shows the functional principle of an ALD wafer reaction chamber according to a preferred embodiment of the invention with the associated supply devices. A wafer chuck 2, on which a wafer 3 is heated to the required process temperature, is located in the reaction chamber 1. The reaction chamber 1 is connected via a valve Vp1 to a TMA tank 4, which for its part is connected, via a pressure regulator 11, to a propellant gas source 13, in such a manner that when pressure is applied by the propellant gas, TMA is forced out in liquid form.

The reaction chamber 1 in which the wafer chuck 2 and the wafer 3 are arranged is connected via a throttling valve 9 to a vacuum pump 14. A pressure-measuring device 8, which is connected to a pressure-regulating device 15 that actuates the throttling valve 9, is provided for the purpose of controlling the pressure in the reaction chamber 1.

Furthermore, the reaction chamber 1 is connected to a purge gas source 19 via a mixing chamber 16, with the interconnection of a valve 17 and a mass flow controller 18. An H₂O tank 20, which is connected to a propellant gas source 22 via a pressure regulator 21, is connected to the mixing chamber 16 via a valve Vp2. The connection was in this case made in such a way that water is forced out of the H₂O tank 20 when pressure is applied by the propellant gas.

The particular feature is that three-way valves are not used, but rather motor vehicle injection valves are used as valves Vp1 and Vp2, so that the TMA or water can be injected directly into the reaction chamber.

The other possible option consists in the TMA and/or the water being injected into a mixing chamber 16 and then being introduced into the reaction chamber 1 together with the purge gas.

FIG. 2 illustrates both variants simultaneously. The TMA is in this case injected directly into the reaction chamber 1, whereas the water is injected into a mixing chamber 16. In a corresponding way, it is also possible for the TMA to be injected into a mixing chamber and/or for the water to be injected directly into the reaction chamber 1.

When the process starts, a predetermined quantity of purge gas is passed out of the purge gas source 19 through the reaction chamber 1. When the angle of the throttling valve 17 has stabilized, the angle is measured and transmitted to the control unit as a fixed set value. Consequently, the mass flow controller 18 will not seek to influence the pressure changes during pulsed operation. When this “calibration” of the throttling valve 18 has been performed for each wafer or batch, long-term instabilities and the wear to the tool and the pumps are compensated for.

Then, the valve Vp1 is opened, so that TMA can flow out of the TMA tank 12 into the reactor 1. For this purpose, the TMA is passed into the TMA tank 12 by a propellant gas from a propellant-gas source 22 via a pressure regulator 21, with the result that an internal pressure which forces the TMA directly into the reactor 1 is built up in the TMA tank 12. At the moment at which the valve Vp1 is closed, the valve 17 is opened to admit the cleaning gas. After the reactor 1 has been sufficiently cleaned, water is passed from a water vapor tank 20 directly into the reactor 1, under control from the pressure regulator 19, using the same basic principle, for which purpose the valve Vp2 is opened.

Then, purge gas is once again passed into the reactor 1. This cycle (TMA, purge, water, purge) is repeated until a sufficiently thick film has been deposited on the wafer 3.

As has already been explained, it is also possible for the TMA from the TMA tank 12 and/or the water from the H₂O tank 20 first of all to be passed into a mixing chamber 16 and from there to be passed into the reaction chamber together with the purge gas.

1. A system for depositing atomic layers on substrates to produce very thin films, the system comprising:
an evacuable reaction chamber;
a wafer chuck for holding at least one wafer;
a source for TMA, the reaction chamber being connected to the source for TMA via a valve;
a source for water, the reaction chamber being connected to the source for water via a valve; and
a source for a cleaning gas, the reaction chamber being connected to the source for the cleaning gas via a valve;
wherein the source for TMA and the source for water are connected to the reaction chamber via devices for directly or indirectly injecting the TMA and the water into the reaction chamber.

2. The system of claim 1, wherein the devices for directly or indirectly injecting comprise valves that are designed as injection valves.

3. The system of claim 2, wherein the injection valves are of similar design to injection valves used in motor vehicles.

4. The system of claim 1, and further comprising a mixing chamber, wherein the devices for injecting the TMA liquid and the water into the reaction chamber are connected to the reaction chamber via the mixing chamber.

5. The system of claim 4 and further comprising a purge gas source, wherein the mixing chamber is connected to the purge gas source.

6. The system of claim 1, wherein the source for TMA comprises a TMA tank, and the source for water comprises an H₂O tank.

7. The system of claim 1, wherein the source for TMA comprises a TMA tank.

8. The system of claim 7, and further comprising a propellant gas source, wherein the TMA tank is connected to the propellant gas source in such a manner that an internal pressure is built up, propelling the TMA out of the TMA tank.

9. The system of claim 1, wherein the source for water comprises an H₂O tank.

10. The system of claim 6, and further comprising a propellant gas source, wherein the H₂O tank is connected to the propellant gas source in such a manner that an internal pressure is built up, propelling the water out of the H₂O tank.

11. A system for depositing atomic layers on substrates to produce very thin films, the system comprising:
an evacuable reaction chamber;
a wafer chuck for holding at least one wafer;
a gaseous source for aluminum, the reaction chamber being connected to the source for TMA via a device for injecting aluminum into the reaction chamber;
a source for water, the reaction chamber being connected to the source for water via a device for injecting water into the reaction chamber; and
a source for a cleaning gas, the reaction chamber being connected to the source for the cleaning gas via a valve.

12. The system of claim 11 wherein the gaseous source for aluminum comprises a source for trimethylaluminium vapor (TMA).

13. The system of claim 11 wherein the device for injecting aluminum into the reaction chamber comprises a device for directly injecting aluminum into the reaction chamber.

14. The system of claim 11 wherein the device for injecting aluminum into the reaction chamber comprises a device for indirectly injecting aluminum into the reaction chamber.

15. The system of claim 11, wherein the device for injecting aluminum into the reaction chamber comprises an injection valve.

16. The system of claim 11, wherein the device for injecting water into the reaction chamber comprises a device for directly injecting water into the reaction chamber.

17. The system of claim 11, wherein the device for injecting water into the reaction chamber comprises a device for indirectly injecting water into the reaction chamber.

18. The system of claim 11, wherein the device for injecting water into the reaction chamber comprises an injection valve.

19. The system of claim 11, wherein the source for TMA comprises a TMA tank and further comprising a propellant gas source, wherein the TMA tank is connected to the propellant gas source in such a manner that an internal pressure is built up, propelling the TMA out of the TMA tank.

20. The system of claim 11, wherein the source for water comprises an H₂O tank and further comprising a propellant gas source, wherein the H₂O tank is connected to the propellant gas source in such a manner that an internal pressure is built up, propelling the water out of the H₂O tank.
